(19) United States
(12) Patent Application Publication
(10) Pub. No.: US 2011/0113906 A1
(43) Pub. Date: May 19, 2011

(54) DEVICE WITH A TURNING FUNCTIONAL MODULE

(75) Inventor: Pasi Kemppinen, Tampere (FI)

(73) Assignee: NOKIA CORPORATION, Espoo (FI)

(21) Appl. No.: 13/000,357

(22) PCT Filed: Jun. 18, 2008
(86) PCT No.: PCT/FI2008/050374

§ 371 Date: Dec. 20, 2010

(51) Int. Cl. H05K 7/16; H05K 5/02

(52) U.S. Cl. 74/96

(57) ABSTRACT

A device comprising a body part (101) and a functional module (102) is presented. The functional module is situated at least partly in a cavity (121) of the body part and is connected to the body part with a supporting mechanism (103, 104, 105, 106) arranged to allow the functional module to be turned relative to the body part. The supporting mechanism is arranged to move an axis of rotation of the functional module in parallel with a surface of the cavity as a response to turning the functional module relative to the body part. Due to the fact that the axis of rotation is moved when turning the functional module, the free space that is needed around the functional module can be minimized. The device can be e.g. a mobile phone and the functional module can be e.g. a camera element of the mobile phone.

### FIELD OF THE INVENTION

The invention relates to a device comprising a body part and a functional module connected to the body part and allowed to be turned relative to the body part. Furthermore, the invention relates to a functional module, to a device body module, and to a method for turning a functional module connected to a body part.

### BACKGROUND

A device, e.g. a mobile phone, may comprise a functional module that is connected to a body part of the device with a supporting mechanism that allows turning the functional module relative to the body part. The functional module may be connected to the body part with a supporting mechanism of the kind mentioned above in order to provide, for example, a slimmer and/or a smaller device and/or in order to achieve other advantages for the mechanics of the device. The functional module can be, for example, a camera element the image capturing direction of which can be adjusted by turning the camera element. One demand for mobile devices can be that the device should be as small and/or slim as possible. Therefore, the supporting mechanism that allows the turning of the functional module should be such that the space needed within the body part for the functional module is as small as possible. For example, free space needed around the functional module for allowing the turning of the functional module should be as small as possible in spite of the fact that the functional module may have an angular shape.

### SUMMARY

In accordance with a first aspect of the invention a new device is provided. The device comprises:
a body part having a cavity, and
a functional module situated at least partly in the cavity and connected to the body part with a supporting mechanism arranged to allow the functional module to be turned relative to the body part,
   wherein the supporting mechanism is arranged to move an axis of rotation of the functional module in parallel with a surface of the cavity as a response to turning the functional module relative to the body part, the axis of rotation of the functional module being a spatial line with respect to which each point of the functional module is in a circular orbit and movement of the axis of rotation making each point of the functional module to be in a non-circular orbit with respect to the cavity.

In accordance with a second aspect of the invention a new device body module is provided. The device body module comprises:
a body part having a cavity, and
a supporting mechanism capable of connecting to a functional module in such a manner that the functional module is situated at least partly in the cavity and allowed to be turned relative to the body part,
   wherein the supporting mechanism is capable of moving an axis of rotation of the functional module in parallel with a surface of the cavity as a response to turning the functional module relative to the body part, the axis of rotation of the functional module being a spatial line with respect to which each point of the functional module is in a circular orbit and movement of the axis of rotation making each point of the functional module to be in a non-circular orbit with respect to the cavity.

The device body module can be used as a building block for manufacturing a device that comprises a body part and a functional module connected to the body part.

In accordance with a third aspect of the invention a new functional module is provided. The functional module comprises contact elements for connecting the functional module to a body part in a manner that the functional module is situated at least partly in a cavity of the body part and the functional module is capable of being turned relative to the body part, wherein an axis of rotation of the functional module is arranged to move in parallel with a surface of the cavity as a response to turning the functional module relative to the body part, the axis of rotation of the functional module being a spatial line with respect to which each point of the functional module is in a circular orbit and movement of the axis of rotation making each point of the functional module to be in a non-circular orbit with respect to the cavity.

The functional module can be used as a building block for manufacturing a device that comprises a body part and the functional module.

In accordance with a fourth aspect of the invention a new method is provided. The method comprises:
turning a functional module relative to a body part, the functional module being situated at least partly in a cavity of the body part and being connected to the body part with a supporting mechanism arranged to allow the functional module to be turned relative to the body part, and moving an axis of rotation of the functional module in parallel with a surface of the cavity when the functional module is turned relative to the body part, the axis of rotation of the functional module being a spatial line with respect to which each point of the functional module is in a circular orbit and movement of the axis of rotation making each point of the functional module to be in a non-circular orbit with respect to the cavity.

A number of embodiments of the invention are described in accompanied dependent claims.

Various exemplifying embodiments of the invention both as to constructions and to methods of operation, together with additional objects and advantages thereof, will be best understood from the following description of specific embodiments when read in connection with the accompanying drawings.

The embodiments of the invention presented in this document are not to be interpreted to pose limitations to the applicability of the appended claims. The verb □to comprise□ is used in this document as an open limitation that does not exclude the existence of also unrecited features. The features recited in depending claims are mutually freely combinable unless otherwise explicitly stated.

### BRIEF DESCRIPTION OF THE FIGURES

The exemplifying embodiments of invention and their advantages are explained in greater detail below with reference to the accompanying drawings, in which

FIGS. 1a, 1b, 1c, 1d, 1e, and 1f illustrate a device according to an embodiment of the invention,

FIGS. 2a, 2b, and 2c illustrate a device according to an embodiment of the invention,

FIGS. 3a, 3b, 3c, 3d, 3e, 3f, and 3g illustrate a device according to an embodiment of the invention,

FIGS. 4a and 4b illustrate a device according to an embodiment of the invention, and

FIG. 5 is a flow chart of a method according to an embodiment of the invention for turning a functional module connected to a body part.

### DETAILED DESCRIPTION

A device according to an embodiment of the invention comprises: (i) a body part having a cavity, (ii) a functional module situated at least partly in the cavity, and (iii) means for connecting the functional module with the body part allowing the functional module to be turned relative to the body part and for moving an axis of rotation of the functional module in parallel with a surface of the cavity as a response to turning the functional module relative to the body part, the axis of rotation of the functional module being a spatial line with respect to which each point of the functional module is in a circular orbit and movement of the axis of rotation making each point of the functional module to be in a non-circular orbit with respect to the cavity.

Due to the fact that the rotational axis is moved in parallel with the surface of the cavity when turning the functional module, the free space that is needed around the functional module for allowing the turning of the functional module can be minimized. The device can be e.g. a mobile phone and the functional module can be e.g. a camera element of the mobile phone.

In a device according to an embodiment of the invention, the means for connecting the functional module with the body part comprise a hinge element joined from a first end of the hinge element to the body part with a first articulation and from a second end of the hinge element to the functional module with a second articulation so as to allow the axis of rotation of the functional module to move in parallel with a surface of the cavity.

In a device according to an embodiment of the invention, the means for connecting the functional module with the body part comprise projections that are movable in arched guide tracks so as to allow the axis of rotation of the functional module to move in parallel with a surface of the cavity.

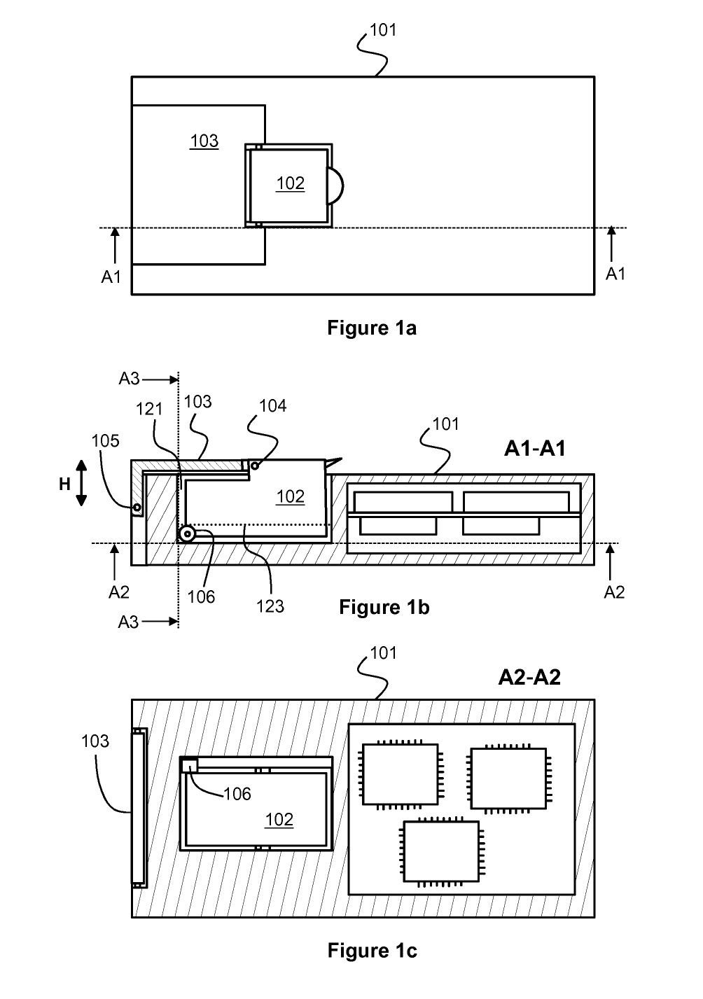

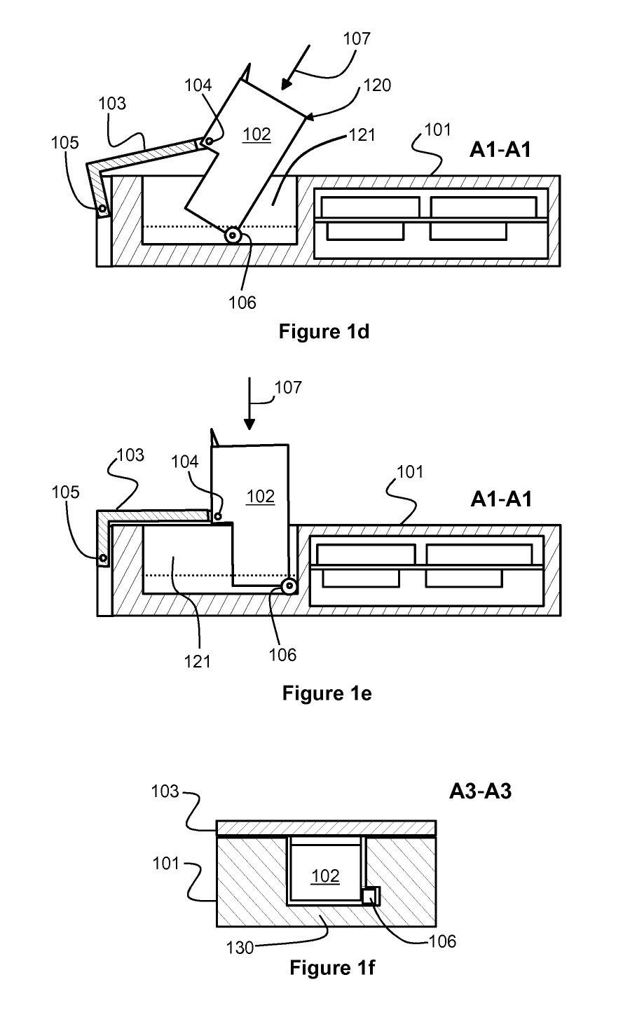

FIG. 1a shows a device according to an embodiment of the invention, FIG. 1b shows a section view A1-A1 of the device, and FIG. 1c shows a section view A2-A2 of the device. The device comprises a body part 101 and a functional module 102 that is situated at least partly in a cavity 121 (FIG. 1b) of the body part and is connected to the body part with a supporting mechanism arranged to allow the functional module to be turned relative to the body part. The supporting mechanism is arranged to move an axis of rotation of the functional module in parallel with a surface of the cavity as a response to turning the functional module relative to the body part. The axis of rotation of the functional module is a spatial line with respect to which each point of the functional module is in a circular orbit and movement of the axis of rotation makes each point of the functional module to be in a non-circular orbit with respect to the cavity. FIGS. 1d and 1e show the section view A1-A1 of the device in exemplifying situations in which the functional module 102 has been turned relative to the body part 101. The functional module 102 may comprise for example a camera element, a speaker element, a microphone, or a combination of two or more of them. An arrow 107 shown in FIGS. 1d and 1e represents an advantageous image capturing direction of a camera element.

In the device shown in FIGS. 1a-1e, the supporting mechanism comprises a hinge element 103 joined from a first end of the hinge element to the body part 101 with a first articulation and from a second end of the hinge element to the functional module 102 with a second articulation so as to allow the axis of rotation of the functional module to move in parallel with the surface of the cavity. The first articulation comprises a hinge pin 105 and the second articulation comprises a hinge pin 104. By selecting an appropriate distance H (FIG. 1b) between the hinge pin 105 and the corner of the hinge element 103 it is possible to reach a desired balance between smooth opening/closing operation and a need for free space around the functional module 102. The supporting mechanism further comprises a roller wheel 106 that is able to run in a groove of the body part. A dashed line 123 (FIG. 1b) represents an upper wall of the groove. Therefore, the groove is arranged to keep the roller wheel 106 in contact with the bottom of the cavity 121. A section view shown in FIG. 1f illustrates how the roller wheel 106 is guided with the groove. The section view shown in FIG. 1f is taken along a line A3-A3 that is shown in FIG. 1b.

The axis of rotation of the functional module is a spatial line with respect to which different points of the functional module are in circular orbits when the functional module is being turned with respect to the body part. It can be seen from FIGS. 1b, 1d, and 1e that the functional module 102 rotates around the hinge pin 104 and also around a shaft of a roller wheel 106 when the functional module is being turned from the position shown in FIG. 1b to the position shown in FIG. 1e. Actually, any spatial line whose location is fixed relative to the functional module 102 and which is perpendicular to the plane of FIGS. 1b, 1d, and 1e and thereby moves in a direction preserving manner relative to the body part 101 when the functional module is turned relative to the body part, can be seen to represent an axis of rotation because a distance from this spatial line to any point of the functional module (due to the fixing) is constant and, therefore, any point of the functional module is in a circular orbit with respect to this spatial line when the functional module is turned relative to the body part. For example, the functional module can be deemed to be rotating also around a spatial line whose location is fixed to a corner 120 (FIG. 1d) of the functional module when the functional module is turned relative to the body part. It should be noted that a spatial line whose location is fixed relative to the functional module 102 and which is perpendicular to the plane of FIGS. 1b, 1d, and 1e does not necessarily have to intersect the functional module in order to represent an axis or rotation. It can be seen from FIGS. 1b, 1d, and 1e that any spatial line that can represent an axis of rotation of the functional module 102 moves in a direction preserving manner relative to the body part 101 when the functional module is turned relative to the body part. This is possible because the functional module is not hinged to any fixed point of the body part. In the embodiment of the invention shown in FIGS. 1a-1e, the functional module is hinged to the hinge element 103 with a hinge pin 104 and, as can be seen from FIGS. 1b, 1d, and 1e, the hinge pin 104 moves in a direction preserving manner relative to the body part when the functional module is turned relative to the body part. As mentioned above, the shaft of the roller wheel 106 can be seen to represent an axis of rotation of the functional module when the functional module is being turned relative to the body part. As can be seen from FIGS. 1b, 1d, and 1e this axis of rotation of the functional module moves in parallel with the surface of the cavity 121 when the functional module is being turned relative to the body part.

As can be seen from FIGS. 1b, 1d, and 1e the volume of the cavity 121 is effectively utilized when this axis of rotation of the functional module is allowed to move along the surface of the cavity. It should be noted that it is not necessary to have a roller wheel. In many cases it may be sufficient that a surface of the functional module 102 is against the surface of the cavity. In this case, there is no mechanical shaft that could act as an axis of rotation of the functional module and that could be moved in parallel with the surface of the cavity but the axis of rotation of the functional module that is moved in parallel with the surface of the cavity is an immaterial spatial line. It should be also noted that the cavity 121 does not necessarily need to have a bottom 130 (FIG. 1f). The axis of rotation of the functional module moves, however, in parallel with the side surfaces of the cavity as can be understood with the aid of FIGS. 1b, 1d, and 1e.

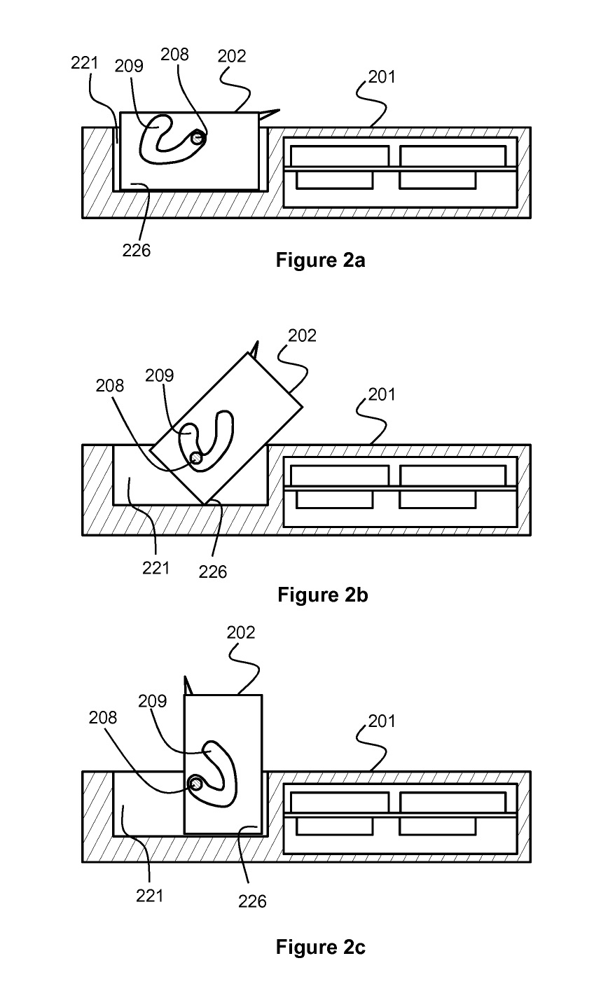

FIGS. 2a, 2b, and 2c illustrate a device according to an embodiment of the invention. FIGS. 2a, 2b, and 2c are section views in a similar manner as FIGS. 1b, 1d, and 1e. The device comprises a body part 201 and a functional module 202 that is situated at least partly in a cavity 221 of the body part and is connected to the body part with a supporting mechanism arranged to allow the functional module to be turned relative to the body part. The supporting mechanism is arranged to move an axis of rotation of the functional module in parallel with a surface of the cavity as a response to turning the functional module relative to the body part. The axis of rotation of the functional module is a spatial line with respect to which each point of the functional module is in a circular orbit and movement of the axis of rotation makes each point of the functional module to be in a non-circular orbit with respect to the cavity. The supporting mechanism comprises projections 208 that are movable in arched guide tracks 209 so as to allow the axis of rotation of the functional module to move in parallel with the surface of the cavity. In the embodiment of the invention shown in FIGS. 2a-2c, the projections are attached to the body part and the arched guide tracks are situated on mutually opposite surfaces of the functional module. Only one arched guide track and a cross section of only one projection are shown in FIGS. 2a-2c. It is also possible to have the arched guide tracks on side walls of the cavity and to have the projections attached to the functional module 202. As can be seen from FIGS. 2a-2c the functional module is rotated around its corner 226 when the functional module is turned relative to the body part. An immaterial spatial line whose location is fixed to the corner 226 represents the axis of rotation of the functional module that moves in parallel with the surface of the cavity as a response to turning the functional module relative to the body part.

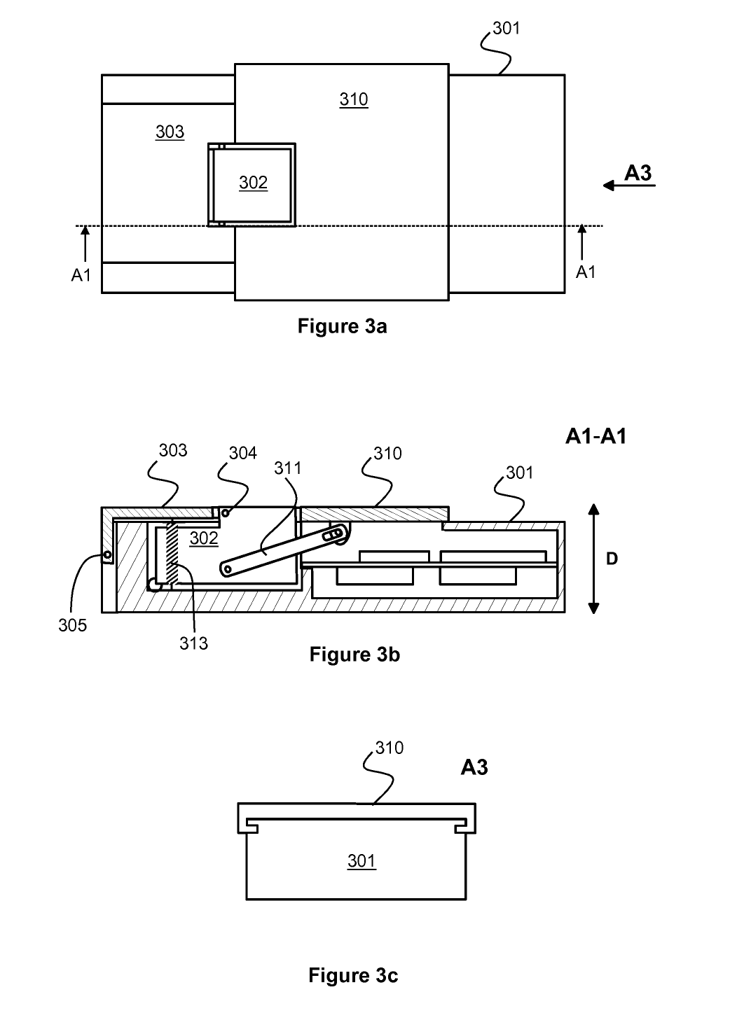

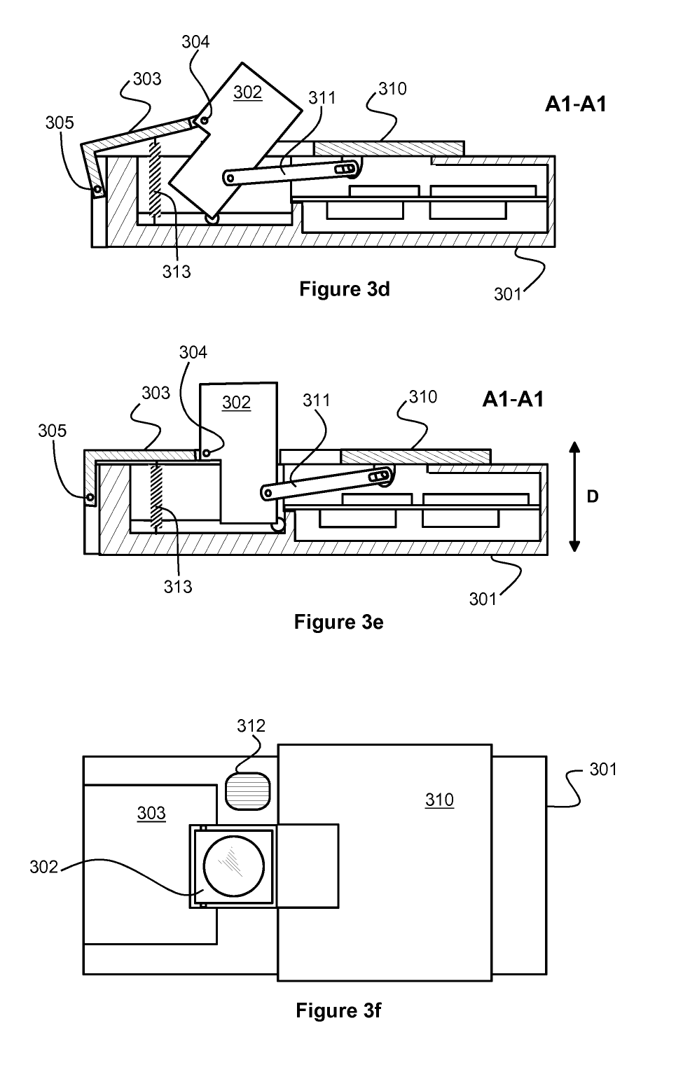

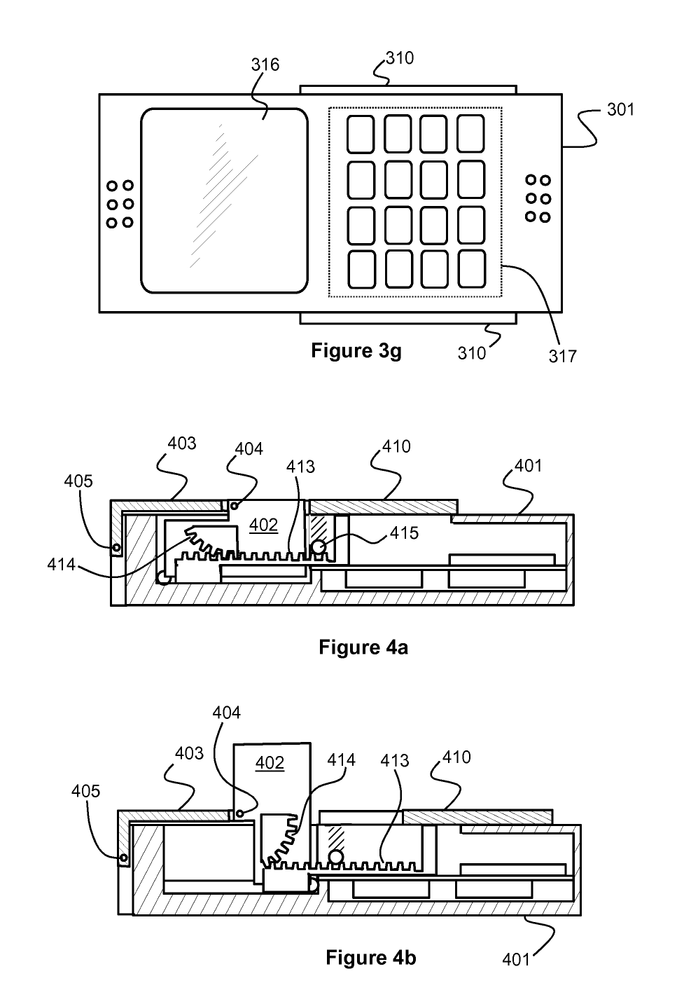

FIG. 3a shows a device according to an embodiment of the invention, FIG. 3b shows a section view A1-A1 of the device, and FIG. 3c shows a butt-end view A3 of the device. The device comprises a body part 301 and a functional module 302 that is situated at least partly in a cavity of the body part and is connected to the body part with a supporting mechanism arranged to allow the functional module to be turned relative to the body part. FIGS. 3d and 3e show the section view A1-A1 of the device in exemplifying situations in which the functional module has been turned relative to the body part. FIG. 3f shows the device from the same viewing angle as FIG. 3a but FIG. 3f corresponds to the exemplifying situation shown in FIG. 3e whereas FIG. 3a corresponds to the exemplifying situation shown in FIG. 3b. FIG. 3g shows the opposite side of the device with respect to what is shown in FIGS. 3a and 3f.

The supporting mechanism is arranged to move an axis of rotation of the functional module 302 in parallel with a surface of the cavity of the body part as a response to turning the functional module relative to the body part. The axis of rotation of the functional module is a spatial line with respect to which each point of the functional module is in a circular orbit and movement of the axis of rotation makes each point of the functional module to be in a non-circular orbit with respect to the cavity. The supporting mechanism comprises a hinge element 303 joined from a first end of the hinge element to the body part 301 with a first articulation and from a second end of the hinge element to the functional module 302 with a second articulation so as to allow the axis of rotation of the functional module to move in parallel with the surface of the cavity. The first articulation comprises a hinge pin 305 and the second articulation comprises a hinge pin 304. The device comprises a sliding element 310 connected to the body part 301 with a sliding contact. The sliding element is mechanically coupled to the functional module 302 so as to turn the functional module relative to the body part as a response to a movement of the sliding element relative to the body part. In the embodiment shown in FIGS. 3a-3g the sliding element is mechanically connected to the functional module with a connecting rod 311 joined from its first end to the functional module 302 with a first articulation and from its second end to the sliding element 310 with a second articulation.

A device according to an embodiment of the invention comprises a spring 313 for keeping the hinge element in one of two extreme positions relative to the body element. As can be seen form FIGS. 3b, 3d and 3e the extreme positions shown in FIGS. 3b and 3e are stable. Therefore, the spring 313 provides a semi-automatic action mechanism.

A device according to an embodiment of the invention is an electronic communication device such as for example a mobile phone. The functional module 302 comprises preferably a camera element the image capturing direction of which is arranged to be turned relative to the body part as a response to turning the camera element relative to the body part 301. The body part is preferably capable of operating as a lens-cover for the camera element in a situation in which the camera element is in its first extreme position relative to the body part. The first extreme position is shown in FIG. 3b. The sliding element 310 is preferably arranged to operate as a shield cover for a flashlight 312 (FIG. 3f) in a situation in which the camera element is in the first extreme position. The electronic communication device may further comprise a display screen 316 (FIG. 3g), a keypad 317 (FIG. 3g), and possible other user-interface means. As can be seen from FIGS. 3e, 3f, and 3g, the display screen 316 can be made perpendicular to the image capturing direction of the camera element and the focal length of the camera element can be made longer than the thickness D (FIGS. 3b and 3e) of the device.

FIGS. 4a and 4b illustrate a device according to an embodiment of the invention. FIGS. 4a and 4b are section views in a similar manner as FIGS. 1b and 1e. The device comprises a body part 401 and a functional module 402 that is situated at least partly in a cavity of the body part and is connected to the body part with a supporting mechanism arranged to allow the functional module to be turned relative to the body part. The supporting mechanism is arranged to move an axis of rotation of the functional module 402 in parallel with a surface of the cavity of the body part as a response to turning the functional module relative to the body part. The supporting mechanism comprises a hinge element 403 joined from a first end of the hinge element to the body part 401 with a first articulation and from a second end of the hinge element to the functional module 402 with a second articulation so as to allow the axis of rotation of the functional module to move in parallel with the surface of the cavity. The first articulation comprises a hinge pin 405 and the second articulation comprises a hinge pin 404. The device comprises a sliding element 410 connected to the body part 401 with a sliding contact. The sliding element is mechanically coupled to the functional module 402 so as to turn the functional module relative to the body part as a response to a movement of the sliding element relative to the body part. In the embodiment shown in FIGS. 4a and 4b the sliding element is connected to a toothed bar 413 and the functional module comprises a toothed arc 414 arranged to be turned as a response to a movement of the toothed bar relative to the body part.

A device according to an embodiment of the invention comprises a spring loaded actuator 415 that is arranged to keep the toothed bar 413 in its prevailing position. Therefore, the functional module has multiple stable positions between its extreme positions that are shown in FIGS. 4a and 4b.

A functional module (e.g. 102 in FIGS. 1a-1f, 202 in FIGS. 2a-2c, 302 in FIGS. 3a-3b and 3d-3f, and 402 in FIGS. 4a and 4b) according to an embodiment of the invention comprises contact elements for connecting the functional module to a body part in a manner that the functional module is situated at least partly in a cavity of the body part and the functional module is capable of being turned relative to the body part, wherein an axis of rotation of the functional module is arranged to move in parallel with a surface of the cavity as a response to turning the functional module relative to the body part, the axis of rotation of the functional module being a spatial line with respect to which each point of the functional module is in a circular orbit and movement of the axis of rotation making each point of the functional module to be in a non-circular orbit with respect to the cavity.

The functional module can be used as a building block for manufacturing a device comprising the functional module and a body part connected to the functional module.

A functional module (e.g. 302 in FIGS. 3a-3b and 3d-3f) according to an embodiment of the invention comprises a contact point for connecting the functional module with a first end of a connecting rod capable of turning the functional module as a response to a movement of a second end of the connecting rod.

A functional module (e.g. 402 in FIGS. 4a and 4b) according to an embodiment of the invention comprises a toothed arc for connecting the functional module with a toothed bar capable of turning the functional module as a response to a movement of the toothed bar.

A functional module (e.g. 302 in FIGS. 3a-3b and 3d-3f) according to an embodiment of the invention is a camera element capable of being connected to an electronic communication device.

A device body module according to an embodiment of the invention comprises:
a body part having a cavity (e.g. 101 in FIGS. 1a-1f, 201 in FIGS. 2a-2c, 301 in FIGS. 3a-3f, and 401 in FIGS. 4a and 4b), and
a supporting mechanism (e.g. 103, 104, 105 in FIGS. 1b, 1d and 1e, 208 in FIGS. 2a-2c, 303, 304, 305, 313 in FIGS. 3b, 3d and 3e, and 403, 404, 405 in FIGS. 4a and 4b) capable of connecting to a functional module in such a manner that the functional module is situated at least partly in the cavity and allowed to be turned relative to the body part,
   wherein the supporting mechanism is capable of moving an axis of rotation of the functional module in parallel with a surface of the cavity as a response to turning the functional module relative to the body part, the axis of rotation of the functional module being a spatial line with respect to which each point of the functional module is in a circular orbit and movement of the axis of rotation making each point of the functional module to be in a non-circular orbit with respect to the cavity.

The device body module can be used as a building block for manufacturing a device comprising the device body module and a functional module connected to the device body module.

A device body module according to an embodiment of the invention comprises a sliding element (e.g. 310 in FIGS. 3a-3g, and 410 in FIGS. 4a and 4b) connected to the body part with a sliding contact, the sliding element being capable of mechanically coupling to the functional module so as to turn the functional module relative to the body part as a response to a movement of the sliding element relative to the body part.

In device body module according to an embodiment of the invention, the supporting mechanism comprises a hinge element (e.g. 103 in FIGS. 1a-1e, 303 in FIGS. 3a, 3b, 3d-3f and 403 in FIGS. 4a and 4b) joined from a first end of the hinge element to the body part with a first articulation, a second end of the hinge element being capable of connecting to the functional module with a second articulation so as to allow the axis of rotation of the functional module to move in parallel with the surface of the cavity.

A device body module according to an embodiment of the invention comprises a spring (e.g. 313 in FIGS. 3b, 3d and 3e) for keeping the hinge element in one of two extreme positions relative to the body element.

In device body module according to an embodiment of the invention, the supporting mechanism comprises projections (e.g. 209 in FIG. 2a-2c) capable of supporting the functional module from arched guide tracks located on surfaces of the functional module so as to allow the axis of rotation of the functional module to move in parallel with the surface of the cavity.

In device body module according to an embodiment of the invention, the supporting mechanism comprises arched guide tracks capable of supporting the functional module from projections located on surfaces of the functional module so as to allow the axis of rotation of the functional module to move in parallel with the surface of the cavity.

A device body module according to an embodiment of the invention is an electronic communication device.

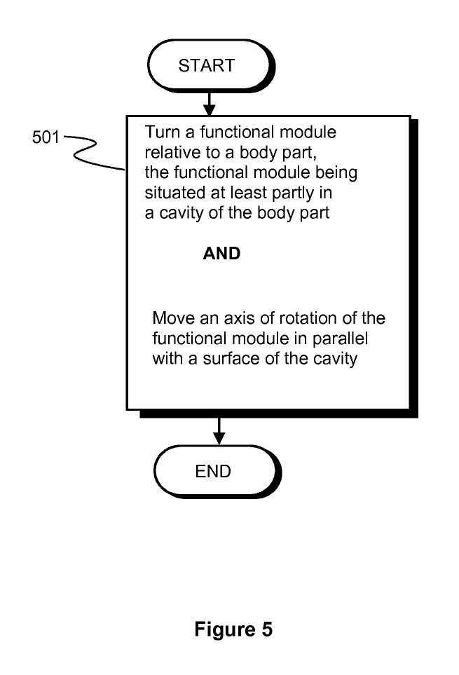

FIG. 5 is a flow chart of a method according to an embodiment of the invention for turning a functional module connected to a body part. The method comprises:
turning, in phase 501, a functional module relative to the body part, the functional module being situated at least partly in a cavity of the body part and being connected to the body part with a supporting mechanism arranged to allow the functional module to be turned relative to the body part, and
moving, in the phase 501, an axis of rotation of the functional module in parallel with a surface of the cavity when the functional module is turned relative to the body part, the axis of rotation of the functional module being a spatial line with respect to which each point of the functional module is in a circular orbit and movement of the axis of rotation making each point of the functional module to be in a non-circular orbit with respect to the cavity.

In a method according to an embodiment of the invention, the functional module is turned relative to the body part by moving a sliding element relative to the body part, the sliding element being connected to the body part with a sliding contact and being mechanically coupled to the functional module so as to turn the functional module relative to the body part when the sliding element is moving relative to the body part.

In a method according to an embodiment of the invention, the sliding element is connected to the functional module with a connecting rod.

In a method according to an embodiment of the invention, the sliding element is connected to a toothed bar and the functional module comprises a toothed arc arranged to be turned when the toothed bar is moving relative to the body part.

In a method according to an embodiment of the invention, the functional module is connected to the body part with a hinge element joined from a first end of the hinge element to the body part with a first articulation and from a second end of the hinge element to the functional module with a second articulation so as to allow the axis of rotation of the functional module to move in parallel with a surface of the cavity.

In a method according to an embodiment of the invention, a spring is used for keeping the hinge element in one of two extreme positions relative to the body part.

In a method according to an embodiment of the invention, the functional module is connected to the body part with projections that are movable in arched guide tracks so as to allow the axis of rotation of the functional module to move in parallel with a surface of the cavity.

In a method according to an embodiment of the invention, the functional module comprises at least one of the following parts: a camera element, a speaker element, and a microphone.

In a method according to an embodiment of the invention, the functional module and the body part are parts of an electronic communication device.

In a method according to an embodiment of the invention, the functional module is a camera element the image capturing direction of which is turned relative to the body part when the functional module is turned relative to the body part.

In a method according to an embodiment of the invention, the body part operates as a lens-cover for the camera element when the camera element is in a first extreme position relative to the body part.

In a method according to an embodiment of the invention, the camera element is turned relative to the body part by moving a sliding element relative to the body part and the sliding element is used as a shield cover for a flashlight when the camera element is in the first extreme position, the sliding element being connected to the body part with a sliding contact and being mechanically coupled to the camera element so as to turn the camera element relative to the body part when the sliding element is moving relative to the body part.

In a method according to an embodiment of the invention, the body part, the camera element, and the sliding element are parts of a mobile phone.

While there have been shown and described and pointed out fundamental novel features of the invention as applied to embodiments thereof, it will be understood that various omissions and substitutions and changes in the form and details of the devices and methods described may be made by those skilled in the art without departing from the scope of the inventive idea defined in the independent claims. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. The specific examples provided in the description given above should not be construed as limiting. Therefore, the invention is not limited merely to the embodiments described above, many variants being possible without departing from the scope of the inventive idea defined in the independent claims.

1-37. (canceled)

38. A device comprising:
a body part having a cavity, and
a functional module situated at least partly in the cavity and connected to the body part with a supporting mechanism arranged to allow the functional module to be turned relative to the body part,
wherein the supporting mechanism is arranged to move an axis of rotation of the functional module in parallel with a surface of the cavity as a response to turning the functional module relative to the body part.

39. A device according to claim 38, comprising a sliding element connected to the body part with a sliding contact, the sliding element being mechanically coupled to the functional module so as to turn the functional module relative to the body part as a response to a movement of the sliding element relative to the body part.

40. A device according to claim 39, wherein the sliding element is connected to the functional module with a connecting rod.

41. A device according to claim 39, wherein the sliding element is connected to a toothed bar and the functional module comprises a toothed arc arranged to be turned as a response to a movement of the toothed bar.

42. A device according to claim 38, wherein the supporting mechanism comprises a hinge element joined from a first end of the hinge element to the body part with a first articulation and from a second end of the hinge element to the functional module with a second articulation so as to allow the axis of rotation of the functional module to move in parallel with a surface of the cavity.

43. A device according to claim 42, comprising a spring for keeping the hinge element in one of two extreme positions relative to the body part.

44. A device according to claim 38, wherein the supporting mechanism comprises projections that are movable in arched guide tracks so as to allow the axis of rotation of the functional module to move in parallel with a surface of the cavity.

45. A device according to claim 38, wherein the functional module comprises at least one of the following parts: a camera element, a speaker element, a microphone.

46. A device according to claim 38, wherein the device is an electronic communication device.

47. A device according to claim 46, wherein the functional module is a camera element the image capturing direction of which is arranged to be turned relative to the body part as a response to turning the camera element relative to the body part.

48. A device according to claim 47, wherein the body part is capable of operating as a lens-cover for the camera element in a situation in which the camera element is in a first extreme position relative to the body part.

49. A device according to claim 48, comprising a sliding element connected to the body part with a sliding contact, the sliding element being mechanically coupled to the camera element so as to turn the camera element relative to the body part as a response to a movement of the sliding element relative to the body part and the sliding element being arranged to operate as a shield cover for a flashlight in a situation in which the camera element is in the first extreme position.

50. A functional module comprising contact elements for connecting the functional module to a body part in a manner that the functional module is situated at least partly in a cavity of the body part and the functional module is capable of being turned relative to the body part, wherein an axis of rotation of the functional module is arranged to move in parallel with a surface of the cavity as a response to turning the functional module relative to the body part.

51. A device body module comprising:
a body part having a cavity, and
a supporting mechanism capable of connecting to a functional module in such a manner that the functional module is situated at least partly in the cavity and allowed to be turned relative to the body part,
wherein the supporting mechanism is capable of moving an axis of rotation of the functional module in parallel with a surface of the cavity as a response to turning the functional module relative to the body part.

52. A device body module according to claim 51, comprising a sliding element connected to the body part with a sliding contact, the sliding element being capable of mechanically coupling to the functional module so as to turn the functional module relative to the body part as a response to a movement of the sliding element relative to the body part.

53. A device body module according to claim 51, wherein the supporting mechanism comprises a hinge element joined from a first end of the hinge element to the body part with a first articulation, a second end of the hinge element being capable of connecting to the functional module with a second articulation so as to allow the axis of rotation of the functional module to move in parallel with the surface of the cavity.

54. A device body module according to claim 51, wherein the supporting mechanism comprises projections capable of supporting the functional module from arched guide tracks located on surfaces of the functional module so as to allow the axis of rotation of the functional module to move in parallel with the surface of the cavity.

55. A device body module according to claim 51, wherein the supporting mechanism comprises arched guide tracks capable of supporting the functional module from projections located on surfaces of the functional module so as to allow the axis of rotation of the functional module to move in parallel with the surface of the cavity.

56. A method comprising:
turning a functional module relative to a body part, the functional module being situated at least partly in a cavity of the body part and being connected to the body part with a supporting mechanism arranged to allow the functional module to be turned relative to the body part, and
moving an axis of rotation of the functional module in parallel with a surface of the cavity when the functional module is turned relative to the body part.

57. A device comprising:
a body part having a cavity,
a functional module situated at least partly in the cavity, and
means for connecting the functional module with the body part allowing the functional module to be turned relative to the body part and for moving an axis of rotation of the functional module in parallel with a surface of the cavity as a response to turning the functional module relative to the body part.
